(19) United States
(12) Patent Application Publication
(10) Pub. No.: US 2026/0194823 A1
(43) Pub. Date: Jul. 9, 2026

(54) OVERLAY METROLOGY SYSTEM WITH DIRECTION-ISOLATED IMAGING

(71) Applicant: KLA Corporation, Milpitas, CA (US)

(72) Inventors: Yoel Feler, Haifa (IL); Vladimir Levinski, Migdal HaEmek (IL); Nireekshan Reddy, Milpitas, CA (US); Alon Alexander Volfman, Migdal HaEmek (IL); Diana Shaphirov, Yoqneam Illit (IL)

(21) Appl. No.: 19/282,629

(22) Filed: Jul. 28, 2025

Related U.S. Application Data
(60) Provisional application No. 63/743,250, filed on Jan. 9, 2025.

(51) Int. Cl. G03F 7/00

(52) U.S. Cl. CPC G03F 7/70208; G03F 7/70133; G03F 7/70633; G03F 7/706831

(57) ABSTRACT

An overlay metrology system may include an illumination sub-system with one or more lenses that can direct illumination to an overlay target on a sample when implementing a metrology recipe. The illumination may include a first illumination dipole and a second illumination dipole. The overlay target may include two or more cells, where each cell may include first-direction features having periodicity along a first direction and second-direction features having periodicity along a second direction. The system may also include an imaging sub-system with an objective lens that can collect diffraction orders of the illumination generated by the overlay target and one or more detectors. The illumination sub-system and the imaging sub-system may be configured to generate a first image and a second image of the overlay target. A controller with one or more processors may generate overlay measurements based on the first and second images.

### CROSS-REFERENCE TO RELATED APPLICATIONS

The present application claims the benefit under 35 U.S.C. § 119 (e) of U.S. Provisional Application Ser. No. 63/743,250, filed Jan. 9, 2025, which is incorporated herein by reference in the entirety.

### TECHNICAL FIELD

The present disclosure relates to overlay metrology, and more particularly, to overlay metrology providing direction-isolated imaging to enable compact target designs and enhanced measurement capabilities.

### BACKGROUND

Overlay metrology plays a crucial role in semiconductor manufacturing processes, enabling precise alignment between different layers of integrated circuits. As device features continue to shrink and manufacturing tolerances tighten, there is an ongoing need for improved overlay measurement techniques. Conventional overlay metrology systems often require separate targets for measuring overlay in different directions, which can consume valuable space on semiconductor wafers. Additionally, existing measurement approaches may face challenges in resolving features along multiple directions simultaneously while maintaining measurement accuracy and precision. Advancements in illumination schemes, target designs, and imaging techniques have the potential to enhance overlay metrology capabilities and support the development of increasingly complex semiconductor devices.

### SUMMARY

In some embodiments, an overlay metrology system is provided. The system may include an illumination sub-system with one or more lenses configured to direct illumination to an overlay target on a sample when implementing a metrology recipe. The illumination may include a first illumination dipole and a second illumination dipole. The overlay target in accordance with the metrology recipe may include two or more cells. Each cell of the two or more cells may include first-direction features having periodicity along a first direction and second-direction features having periodicity along a second direction.

In some embodiments, the system may include an imaging sub-system with an objective lens configured to collect diffraction orders of the illumination generated by the overlay target and one or more detectors. The illumination sub-system and the imaging sub-system may be configured in accordance with the metrology recipe to generate a first image of the overlay target based on first-order diffraction of the first illumination dipole by the first-direction features. The first-direction features may be resolved and the second-direction features may be unresolved on the first image. The illumination sub-system and the imaging sub-system may also be configured to generate a second image of the overlay target based on first-order diffraction of the second illumination dipole by the second-direction features. The second-direction features may be resolved and the first-direction features may be unresolved in the second image.

In some embodiments, the system may include a controller with one or more processors configured to execute program instructions causing the one or more processors to generate a first overlay measurement along the first direction based on the first image and generate a second overlay measurement along the second direction based on the second image.

In some embodiments, the illumination sub-system and the imaging sub-system may be configured in accordance with the metrology recipe to provide that first-order diffraction from the second-direction features is outside a collection numerical aperture of the objective lens when generating the first image and further provide that first-order diffraction from the first-direction features is outside the collection numerical aperture of the objective lens when generating the second image.

In some embodiments, the illumination sub-system and the imaging sub-system may be configured in accordance with the metrology recipe to provide that first-order diffraction from the second-direction features is blocked when generating the first image and further provide that first-order diffraction from the first-direction features is blocked when generating the second image.

In some embodiments, the one or more detectors may include a first detector configured to generate the first image and a second detector configured to generate the second image simultaneously with the first image.

In some embodiments, the first illumination dipole and the second illumination dipole may have different wavelengths. The imaging sub-system may further include one or more wavelength-selective optics to direct the first-order diffraction of the first illumination dipole by the first-direction features to the first detector and direct the first-order diffraction of the second illumination dipole by the second-direction features to the second detector.

In some embodiments, the first illumination dipole and the second illumination dipole may have orthogonal polarizations. The imaging sub-system may further include one or more polarization-selective optics to direct the first-order diffraction of the first illumination dipole by the first-direction features to the first detector and direct the first-order diffraction of the second illumination dipole by the second-direction features to the second detector.

In some embodiments, the imaging sub-system may further include one or more prisms in a collection pupil to direct the first-order diffraction of the first illumination dipole by the first-direction features to the first detector and direct the first-order diffraction of the second illumination dipole by the second-direction features to the second detector.

In some embodiments, the first illumination dipole may include a first pair of mutually-coherent beams. The second illumination dipole may include a second pair of mutually-coherent beams.

In some embodiments, the first pair of mutually-coherent beams and the second pair of mutually-coherent beams may be incoherent with respect to each other.

In some embodiments, the illumination sub-system may direct the first pair of mutually-coherent beams and the second pair of mutually-coherent beams to the overlay target at incidence angles outside a collection numerical aperture of the objective lens.

In some embodiments, the illumination may be at least one of spatially or temporally incoherent.

In some embodiments, the illumination sub-system may direct the first illumination dipole and the second illumination dipole to the overlay target through the objective lens.

In some embodiments, the two or more cells of the overlay target may include one or more first cells and one or more second cells. The first-direction features and the second-direction features in the one or more first cells may be located in a first layer of the sample. The first-direction features in the one or more second cells may be located in a second layer of the sample. The second-direction features in the one or more second cells may be located in a third layer of the sample.

In some embodiments, the one or more first cells and the one or more second cells may have a common center of symmetry by design.

In some embodiments, the two or more cells of the overlay target may include one or more first cells and one or more second cells. The first-direction features and the second-direction features in the one or more first cells may be located in a first layer of the sample. The first-direction features and the second-direction features in the one or more second cells may be located in a second layer of the sample.

In some embodiments, the one or more first cells and the one or more second cells may have a common center of symmetry by design.

In some embodiments, the two or more cells of the overlay target may include one or more first cells and one or more second cells. The first-direction features in the one or more first cells may be located in a first layer of the sample. The second-direction features in the one or more first cells may be located in a second layer of the sample. The first-direction features in the one or more second cells may be located in the first layer of the sample.

In some embodiments, the second-direction features in the one or more first cells may be located in the second layer of the sample.

In some embodiments, the second-direction features in the one or more first cells may be located in a third layer of the sample.

In some embodiments, the one or more first cells and the one or more second cells may have a common center of symmetry by design.

In some embodiments, an overlay metrology method is provided. The method may include illuminating an overlay target on a sample with illumination including a first illumination dipole and a second illumination dipole. The overlay target may include two or more cells. Each cell of the two or more cells may include first-direction features having periodicity along a first direction and second-direction features having periodicity along a second direction.

In some embodiments, the method may include generating a first image on a first detector based on first-order diffraction of the first illumination dipole by the first-direction features. The first-direction features may be resolved and the second-direction features may be unresolved in the first image.

In some embodiments, the method may include generating a second image of the overlay target based on first-order diffraction of the second illumination dipole by the second-direction features. The second-direction features may be resolved and the first-direction features may be unresolved in the second image.

In some embodiments, the method may include determining a first overlay measurement along the first direction based on the first image and generate a second overlay measurement along the second direction based on the second image.

In some embodiments, an overlay metrology target is provided. The target may include two or more cells on a sample. Each cell of the two or more cells may include first-direction features having periodicity along a first direction and second-direction features having periodicity along a second direction. The two or more cells may include one or more first cells and one or more second cells. The first-direction features and the second-direction features in the one or more first cells may be located in a first layer of the sample. The first-direction features in the one or more second cells may be located in a second layer of the sample. The second-direction features in the one or more second cells may be located in a third layer of the sample.

In some embodiments, the one or more first cells and the one or more second cells may have a common center of symmetry by design.

In some embodiments, pitches of the first-direction features and the second-direction features may be selected in accordance with a metrology recipe based on known properties of a first illumination dipole and a second illumination dipole of an overlay metrology system configured to generate overlay measurements of the overlay metrology target. The metrology recipe may provide that first-order diffraction from the second-direction features is outside a collection numerical aperture of an objective lens of the overlay metrology system and further provides that first-order diffraction from the first-direction features is outside the collection numerical aperture of the objective lens.

It is to be understood that both the foregoing general description and the following detailed description are exemplary and explanatory only and are not necessarily restrictive of the invention as claimed. The accompanying drawings, which are incorporated in and constitute a part of the specification, illustrate embodiments of the invention and together with the general description, serve to explain the principles of the invention.

### BRIEF DESCRIPTION OF FIGURES

The numerous advantages of the disclosure may be better understood by those skilled in the art by reference to the accompanying figures.

FIG. 1A illustrates a block diagram of an overlay metrology system, in accordance with one or more embodiments of the present disclosure.

FIG. 1B shows a schematic view of components in an overlay metrology system, in accordance with one or more embodiments of the present disclosure.

FIG. 2A depicts top views of an overlay target formed as a cross-hatched target, in accordance with one or more embodiments of the present disclosure.

FIG. 2B presents a schematic view of an overlay target with 2D structures, in accordance with one or more embodiments of the present disclosure.

FIG. 2C illustrates another example of an overlay target with mixed structures, in accordance with one or more embodiments of the present disclosure.

FIGS. 3A and 3B show schematic views of illumination and collection pupils for X-direction measurements, in accordance with one or more embodiments of the present disclosure.

FIG. 3C depicts an X-direction image of an overlay target, in accordance with one or more embodiments of the present disclosure.

FIGS. 3D and 3E illustrate pupil diagrams for Y-direction measurements, in accordance with one or more embodiments of the present disclosure.

FIG. 3F shows a Y-direction image of an overlay target, in accordance with one or more embodiments of the present disclosure.

FIGS. 4A and 4B present schematic diagrams of pupils for rotated X-direction measurements, in accordance with one or more embodiments of the present disclosure.

FIGS. 4C and 4D illustrate schematic diagrams of pupils for rotated Y-direction measurements, in accordance with one or more embodiments of the present disclosure.

FIG. 5 shows a flowchart of a method for performing overlay measurements, in accordance with one or more embodiments of the present disclosure.

### DETAILED DESCRIPTION

Reference will now be made in detail to the subject matter disclosed, which is illustrated in the accompanying drawings. The present disclosure has been particularly shown and described with respect to certain embodiments and specific features thereof. The embodiments set forth herein are taken to be illustrative rather than limiting. It should be readily apparent to those of ordinary skill in the art that various changes and modifications in form and detail may be made without departing from the spirit and scope of the disclosure.

Embodiments of the present disclosure are directed to systems and methods providing enhanced overlay metrology capabilities through dipole or quadrupole illumination providing direction-isolated imaging of periodic features of an overlay target.

In embodiments, the overlay metrology systems and methods described herein provide overlay measurements of overlay targets that incorporate orthogonal features in each cell. These features include periodicity along both x-direction and y-direction within individual cells of the target.

In embodiments, an overlay target is illuminated with a first illumination dipole for x-direction measurements and a second illumination dipole for y-direction measurements. The properties of these illumination dipoles (e.g., wavelength, incidence angle, or the like) are co-selected with the overlay target properties according to a metrology recipe to provide direction-isolated imaging. For example, an x-direction image in which only features with periodicity along an x-direction are resolved may be generated based on selected diffraction lobes from the first illumination dipole that exclude first-order (and higher) diffraction of the first illumination dipole from a collection pupil. Similarly, a y-direction image in which only features with periodicity along an y-direction are resolved may be generated based on selected diffraction lobes from the second illumination dipole that exclude first-order (and higher) diffraction of the second illumination dipole from the collection pupil.

The systems and methods provide flexibility in capturing the x-direction and y-direction images. In some cases, the images may be captured sequentially using a single detector. In other cases, simultaneous capture may be achieved using two separate detectors. For simultaneous detection with two detectors, the systems may employ various techniques to divide the associated diffraction lobes into different imaging channels. These techniques may include wavelength-based separation, polarization-based separation, or pupil-based separation.

Additional embodiments of the present disclosure are directed to an overlay target design that may be suitable for, but not limited to, direction-isolated imaging using the systems and methods disclosed herein. In particular, an overlay target may include a first set of cells with two-dimensional (2D) periodic features in a first set of cells, where the 2D periodic features a single layer (e.g., a current layer of the sample). The overlay target may further include a second set of cells with overlapping one-dimensional (1D) periodic features (e.g., grating features), where the overlapping 1D periodic features are located in two different layers (e.g., two different previous layers of the sample).

The overlay targets used in these systems may vary in size. In some cases, the target size may range from 4 micrometers per side to 16 micrometers per side, allowing for efficient use of wafer space while maintaining measurement accuracy. However, these examples are merely illustrative and not limiting on the scope of the present disclosure.

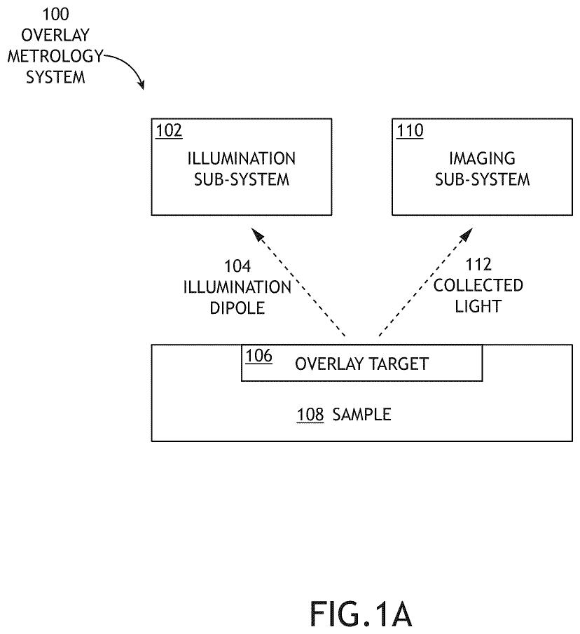

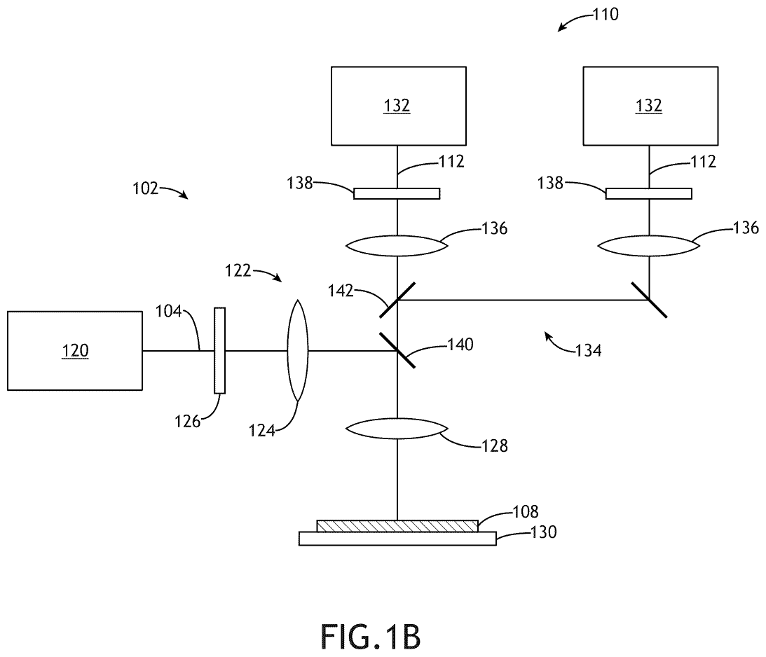

Referring now to FIGS. 1A-5, systems and methods providing direction-isolated imaging of overlay targets with orthogonal features are described in greater detail, in accordance with one or more embodiments of the present disclosure.

FIG. 1A illustrates a block diagram of an overlay metrology system 100, in accordance with one or more embodiments of the present disclosure.

In embodiments, the overlay metrology system 100 includes an illumination sub-system 102 that directs illumination in the form of two illumination dipoles 104 to an overlay target 106 positioned on a sample 108, where the illumination dipoles 104 may be directed to the overlay target 106 simultaneously or sequentially.

In embodiments, the overlay metrology system 100 includes an imaging sub-system 110 configured to receive diffracted light 112 from the overlay target 106. For example, the diffracted light 112 may include selective diffraction lobes of the illumination dipoles by the overlay target 106. As is described throughout the present disclosure, properties of the illumination dipoles 104 (e.g., wavelength, incidence angle, polarization, or the like) may be co-selected with properties of the overlay target 106 (e.g., feature pitch along selected directions, or the like) in accordance with a metrology recipe to provide that the diffracted light 112 collected by the imaging sub-system 110 is limited to selected diffraction orders. Further, in a case of multiple dipoles 104, the different dipoles 104 may have the same or different properties (e.g., wavelength, incidence angle, polarization, or the like).

More generally, any aspect of the overlay metrology system 100 or the overlay target 106 may be designed or controlled based on a metrology recipe to ensure proper operation. For example, a metrology recipe may include various design parameters of an overlay target 106 including, but not limited to, a number or orientation of cells in the overlay target 106 or properties of fabricated features in any of the cells (e.g., number of features, layer of the sample 108 on which features are located, directions of periodicity, dimensions, or the like). As another example, a metrology recipe of may include parameters associated with illumination (e.g., illumination dipoles 104) such as, but not limited to, incidence angles (e.g., azimuth and/or polar incidence angles), polarization, phase characteristics, or wavelength. As another example, a metrology recipe may include parameters associated with diffracted light 112 used to generate an image such as, but not limited to, collection angles, polarization, phase characteristics, or wavelength. As another example, a metrology recipe may include sampling characteristics such as, but not limited to, locations on a sample 108 to be measured (e.g., locations of dedicated overlay targets 106 or device features to be characterized) or focus characteristics.

In some embodiments, the overlay metrology system 100 further includes a controller 114 including one or more processors 116 configured to execute program instructions stored in memory 118 (e.g., a memory device). The processors 116 of the controller 114 may then execute program instructions causing the processors 116 to implement any of the various steps described in the present disclosure either directly or indirectly (e.g., by generating control signals to control components of the metrology system 100 and/or external components). For example, the processors 116 of the controller 114 may receive direction-specific images of the overlay target 106 (e.g., an x-direction image and a y-direction image) generated with selected diffraction orders (e.g., the diffracted light 112). As another example, the processors 116 of the controller 114 may generate direction-specific overlay measurements of the sample 108 (e.g., an x-direction overlay measurement based on an x-direction image and a y-direction overlay measurement based on a y-direction image). As another example, the processors 116 of the controller 114 may generate correctables to control, based on the overlay measurements, one or more process tools such as, but not limited to, a lithography tool, an etching tool, or a polishing tool. Correctables may be generated to control one or more process tools in any combination of a feedback control loop or a feed-forward control loop. As an illustration, feedback correctables generated in response to metrology measurements on a sample 108 may control a process tool during the fabrication of additional samples in the same or different lots (e.g., in response to drifts of the process tools). As another illustration, feed-forward correctables generated in response metrology measurements on a sample 108 may be used to control a process tool during fabrication of additional features on the sample 108 in future process steps.

The one or more processors 116 of a controller 114 may include any processing element known in the art. In this sense, the one or more processors 116 may include any microprocessor-type device configured to execute algorithms and/or instructions. In some embodiments, the one or more processors 116 may consist of a desktop computer, mainframe computer system, workstation, image computer, parallel processor, or any other computer system (e.g., networked computer) configured to execute a program configured to operate the metrology system 100, as described throughout the present disclosure. It is further recognized that the term “processor” may be broadly defined to encompass any device having one or more processing elements, which execute program instructions from a non-transitory memory 118. Further, the steps described throughout the present disclosure may be carried out by a single controller 114 or, alternatively, multiple controllers. Additionally, the controller 114 may include one or more controllers housed in a common housing or within multiple housings. In this way, any controller or combination of controllers may be separately packaged as a module suitable for integration into metrology system 100.

The memory 118 may include any storage medium known in the art suitable for storing program instructions executable by the associated one or more processors 116. For example, the memory 118 may include a non-transitory memory medium. By way of another example, the memory 118 may include, but is not limited to, a read-only memory, a random-access memory, a magnetic or optical memory device (e.g., disk), a magnetic tape, a solid-state drive and the like. It is further noted that memory 118 may be housed in a common controller housing with the one or more processors 116. In some embodiments, the memory 118 may be located remotely with respect to the physical location of the one or more processors 116 and controller 114. For instance, the one or more processors 116 of controller 114 may access a remote memory (e.g., server), accessible through a network (e.g., internet, intranet and the like). Therefore, the above description should not be interpreted as a limitation on the present invention but merely an illustration.

The components of the overlay metrology system 100 work together to perform precise overlay measurements. The illumination sub-system 102 provides the necessary illumination for imaging the overlay target 106. The imaging sub-system 110 captures the images of the overlay target 106, while the controller 114 coordinates the operation of both sub-systems and processes the captured images. By analyzing the diffracted light 112 from the overlay target 106, the overlay metrology system 100 can determine the overlay error between different layers of the sample 108.

Referring now to FIG. 1B, various additional aspects of the overlay metrology system 100 are described, in accordance with one or more embodiments of the present disclosure. FIG. 1B shows a schematic view of components in an overlay metrology system, in accordance with one or more embodiments of the present disclosure.

In some embodiments, the illumination sub-system 102 includes an illumination source 120 configured to generate illumination in the form of at least one illumination dipole 104. The illumination from the illumination source 120 may include one or more selected wavelengths of light including, but not limited to, ultraviolet (UV) radiation, visible radiation, or infrared (IR) radiation. For example, the illumination sub-system 102 may include one or more apertures at an illumination pupil plane to divide illumination from the illumination source 120 into one or more illumination dipoles 104, where each illumination dipole 104 includes two illumination lobes. In this regard, the illumination sub-system 102 may provide dipole illumination (e.g., with a single illumination dipole 104), quadrupole illumination (e.g., with two illumination dipoles 104), or the like. Further, the spatial profile of the one or more illumination dipoles 104 on the sample 108 may be controlled by a field-plane stop to have any selected spatial profile.

The illumination source 120 may include any type of illumination source suitable for providing at least one illumination dipole 104. In some embodiments, the illumination source 120 is a laser source. For example, the illumination source 120 may include, but is not limited to, one or more narrowband laser sources, a broadband laser source, a supercontinuum laser source, a white light laser source, or the like. In some embodiments, the illumination source 120 includes a laser-sustained plasma (LSP) source. For example, the illumination source 120 may include, but is not limited to, a LSP lamp, a LSP bulb, or a LSP chamber suitable for containing one or more elements that, when excited by a laser source into a plasma state, may emit broadband illumination. In some embodiments, the illumination source 120 includes a lamp source. For example, the illumination source 120 may include, but is not limited to, an arc lamp, a discharge lamp, an electrode-less lamp, or the like.

In some embodiments, the illumination dipoles 104 may be spatially and/or temporally incoherent or coherent, providing flexibility in the illumination characteristics. The coherence properties of the illumination dipoles 104 may be tailored to suit specific measurement requirements or target designs. In some variations, the illumination lobes within a particular illumination dipole 104 may be incoherent with respect to each other, while in other variations, the lobes may be mutually coherent. Additionally, the coherence properties may vary between different illumination dipoles 104. For example, a first illumination dipole may have mutually coherent illumination lobes, and a second illumination dipole may also have mutually coherent illumination lobes, but the first and second illumination dipoles may be either coherent or incoherent with respect to each other.

In some embodiments, the illumination sub-system 102 directs the one or more illumination dipoles 104 to the overlay target 106 on the sample 108 via an illumination pathway 122. The illumination pathway 122 may include one or more optical components suitable for modifying and/or conditioning the one or more illumination dipoles 104 as well as directing the one or more illumination dipoles 104 to the overlay target 106. In some embodiments, the illumination pathway 122 includes one or more illumination-pathway lenses 124 (e.g., to collimate the one or more illumination dipoles 104, to relay pupil and/or field planes, or the like). In some embodiments, the illumination pathway 122 includes one or more illumination-pathway optics 126 to shape or otherwise control the one or more illumination dipoles 104. For example, the illumination-pathway optics 126 may include, but are not limited to, one or more polarizers, one or more phase-control optics (e.g., waveplates), one or more field stops, one or more pupil stops, one or more one or more filters (e.g., spatial and/or spectral filters), one or more beam splitters, one or more diffusers, one or more homogenizers, one or more apodizers, one or more beam shapers, or one or more mirrors (e.g., static mirrors, translatable mirrors, scanning mirrors, or the like).

In some embodiments, the sample 108 is disposed on a sample stage 130 suitable for securing the sample 108 and further configured to position the sample 108 with respect to the illumination sub-system 102.

In some embodiments, the illumination sub-system 102 includes an objective lens 128, which may be used by and/or incorporated within the illumination subsystem 102 and/or the imaging subsystem 110.

The illumination sub-system 102 may direct the illumination dipoles 104 to the overlay target 106 using different optical configurations. For example, the illumination sub-system 102 may employ a through-the-lens (TTL) configuration where the illumination dipoles 104 are directed through the objective lens 128 to the overlay target 106. As another example, the illumination sub-system 102 may utilize an outside-the-lens (OTL) configuration where the illumination dipoles 104 are directed to the overlay target 106 without passing through the objective lens 128. In the OTL configuration, the illumination sub-system 102 may include additional optics such as lenses, mirrors, or other optical elements to properly direct and focus the illumination dipoles 104 onto the overlay target 106. The choice between TTL and OTL configurations may depend on factors such as the desired illumination angles, system design constraints, or specific measurement requirements. In some cases, the illumination sub-system 102 may be adaptable to switch between TTL and OTL configurations, providing flexibility in measurement capabilities.

In some embodiments, the imaging sub-system 110 images the overlay target 106 onto at least one detector 132 through a collection pathway 134 based on diffracted light 112. As described throughout the present disclosure, the diffracted light 112 may include selected diffraction orders to facilitate direction-isolated imaging. For example, the collection pathway 134 may include optics to collect diffracted light 112 from the overlay target 106 and form an image on the detector 132 based on this diffracted light 112. In this way, the detector 132 may generate signals associated with the overlay target 106 based on portions of an image of the sample 108 including the overlay target 106.

The collection pathway 134 may include one or more optical elements suitable for modifying and/or conditioning the diffracted light 112 from the sample 108. In some embodiments, the collection pathway 134 includes one or more collection-pathway lenses 136 (e.g., to collimate the diffracted light 112, to relay pupil and/or field planes, or the like), which may include, but is not required to include, the objective lens 128. In some embodiments, the collection pathway 134 includes one or more collection-pathway optics 138 to shape or otherwise control the diffracted light 112. For example, the collection-pathway optics 138 may include, but are not limited to, one or more polarizers, one or more phase-control optics (e.g., waveplates), one or more field stops, one or more pupil stops, one or more filters, one or more beam splitters, one or more diffusers, one or more homogenizers, one or more apodizers, one or more beam shapers, or one or more mirrors (e.g., static mirrors, translatable mirrors, scanning mirrors, or the like).

The detector 132 may be placed at a field plane conjugate to the sample 108. Further, the detector 132 may generally include any type of sensor suitable for imaging the sample 108. In some embodiments, the detector 132 is suitable for characterizing a static sample such as, but not limited to, a charge-coupled device (CCD) or a complementary metal-oxide semiconductor (CMOS) device. In this regard, the detector 132 may generate a two-dimensional image in a single measurement. In some embodiments, the detector 132 is suitable for characterizing a moving sample (e.g., a scanned sample). In this regard, the imaging sub-system 110 may operate in a scanning mode in which the sample 108 is scanned with respect to a measurement field during a measurement. For example, the detector 132 may include a 2D pixel array with a capture time and/or a refresh rate sufficient to capture one or more images during a scan within selected image tolerances (e.g., image blur, contrast, sharpness, or the like). By way of another example, the detector 132 may include a line-scan detector to continuously generate an image one line of pixels at a time. By way of another example, the detector 132 may include a time-delay integration (TDI) detector.

The imaging sub-system 110 may be configured with one or multiple channels to accommodate various measurement requirements. In a single-channel configuration, the system may utilize one detector 132 for sequential imaging of the overlay target 106. This approach may allow for compact system design and simplified optical paths. Alternatively, a two-channel setup may enable simultaneous direction-isolated imaging, where diffracted light 112 from distinct illumination dipoles 104 is directed to separate detectors 132 in different channels.

In a multi-channel configuration, the imaging sub-system 110 may be designed to separate the diffracted light 112 generated by different illumination dipoles 104. In some cases, the illumination dipoles 104 have different properties (e.g., wavelength, polarization, incidence angle direction, or the like) that may facilitate separation of diffracted light 112 from the different dipoles 104. For example, diffracted light 112 resulting from a first illumination dipole 104 oriented along a first direction may be directed to a first detector 132, while diffracted light 112 from a second illumination dipole 104 oriented along a second direction may be simultaneously directed to a second detector 132. This separation may allow for concurrent acquisition of direction-isolated images, potentially improving measurement throughput and enabling real-time comparison of overlay measurements along different directions.

To achieve multi-channel functionality, the imaging sub-system 110 may incorporate various channel-splitting optics 142 (e.g., beamsplitters, wavelength-selective optics, polarization-selective optics, prisms, or the like) designed to split the diffracted light 112 into different channels.

In some embodiments, the channel-splitting optics 142 may split the diffracted light 112 into different channels based on based on wavelength. In this configuration, different illumination dipoles 104 may have distinct spectral characteristics (e.g., wavelengths). The imaging sub-system 110 may then employ wavelength-selective channel-splitting optics 142 such as, but not limited to, dichroic mirrors or spectral filters, to separate the diffracted light 112 based on wavelength and direct it to the appropriate detector 132.

In some embodiments, the channel-splitting optics 142 may split the diffracted light 112 based on polarization. In this configuration, different illumination dipoles 104 may have distinct polarization states. The imaging subsystem 110 may then may use polarization-sensitive channel-splitting optics 142 such as, but not limited to, polarizing beam splitters or waveplates to separate the diffracted light 112 based on its polarization state.

In some embodiments, the channel-splitting optics 142 may split the diffracted light 112 based on location of diffraction lobes in the collection pupil 304. In this configuration, the channel-splitting optics 142 may include components such as, but not limited to, prisms or mirrors in the collection pupil 304 arranged to separate the diffracted light 112 associated with the different illumination dipoles 104 based on the locations of the associated diffraction lobes in the collection pupil 304.

The illumination pathway 122 and the collection pathway 134 of the overlay metrology system 100 may be oriented in a wide range of configurations. For example, as illustrated in FIG. 1B, the overlay metrology system 100 may include a beamsplitter 140 oriented such that a common objective lens 128 may simultaneously direct the one or more illumination dipoles 104 to the sample 108 and collect diffracted light 112 from the sample 108 (e.g., the beamsplitter 140 may enable a TTL configuration). As another example, the illumination pathway 122 and the collection pathway 134 may contain non-overlapping optical paths and/or separate optical components (e.g., in an OTL configuration).

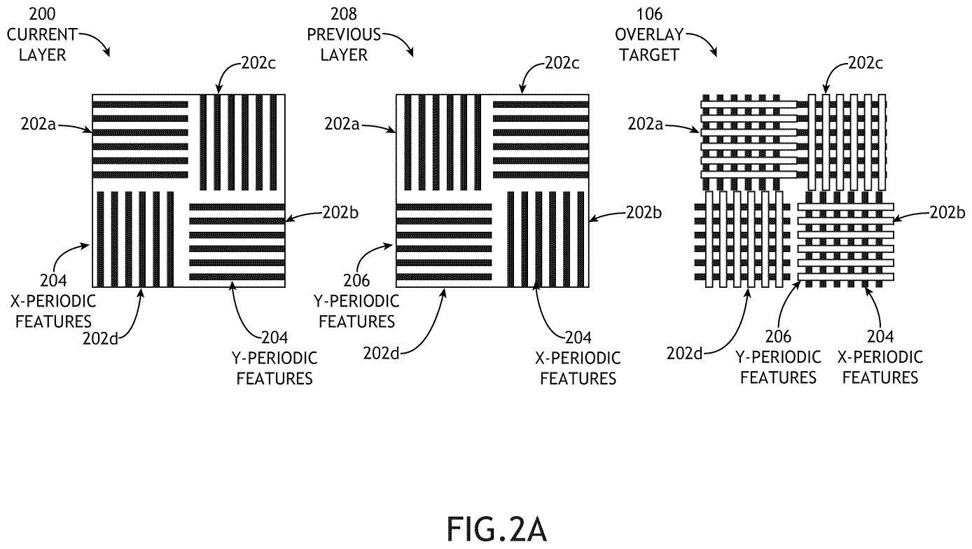

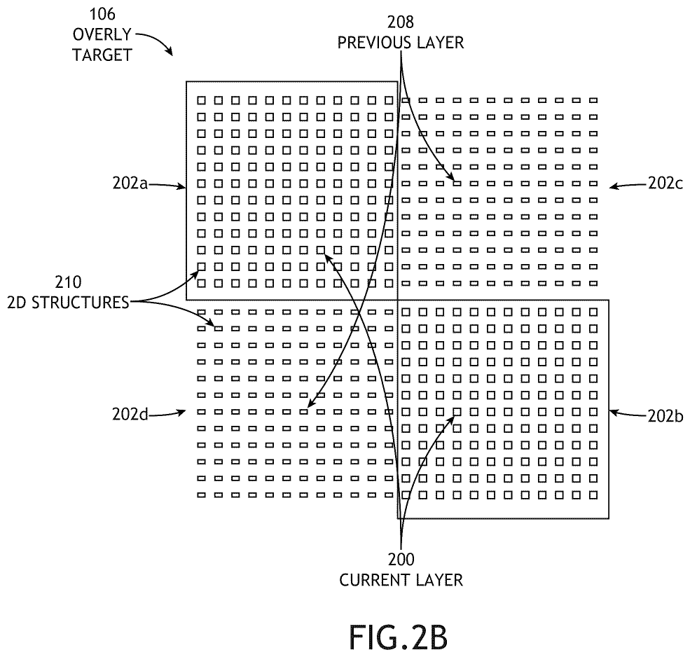

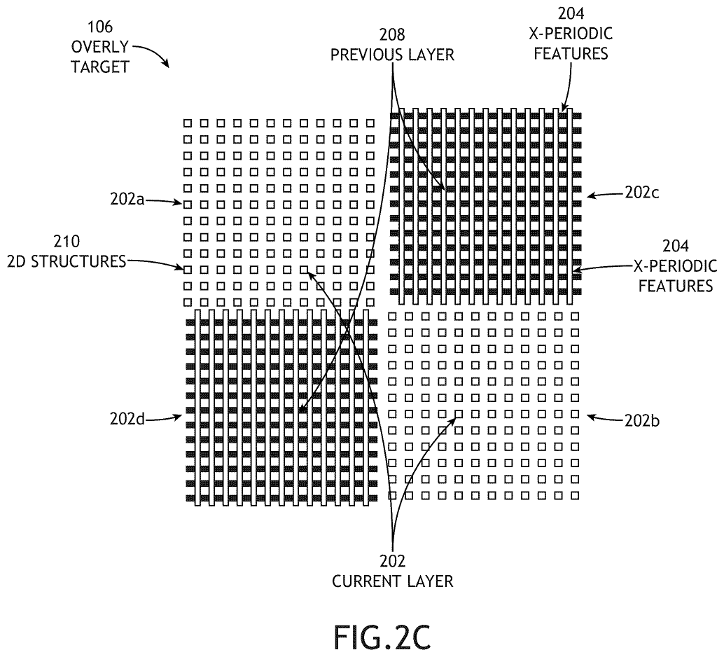

Referring now to FIGS. 2A-2C, various non-limiting designs of an overlay target 106 suitable for direction-isolated imaging are described, in accordance with one or more embodiments of the present disclosure.

An overlay target 106 may include one or more cells, each containing features having periodicity oriented along a first direction and second-direction. The first direction and the second direction may be orthogonal to each other. For example, each cell may include x-direction features with periodicity along an x-direction and y-direction features with periodicity along a y-direction, where the x-direction is orthogonal to the y-direction. In some embodiments, the x-direction features and y-direction features within a particular cell may be located on a common layer, forming two-dimensional (2D) structures. In some embodiments, the x-direction features and y-direction features within a particular cell may be located on different layers of the sample 108.

In embodiments, an overlay target 106 includes two or more cells, where each cell includes first-direction features having periodicity along a first direction and second-direction features having periodicity along a second direction. The first direction and the second direction may be orthogonal to each other, such as x-direction and y-direction. For example, FIGS. 2A-2C depict x-periodic features 204 having periodicity along an x direction (e.g., horizontal in the figures) and further depict y-periodic features 206 having periodicity along a y direction (e.g., vertical in the figures).

The first-direction features and the second-direction features in a particular cell may be located in any layer of the sample 108. For example, the first-direction features and the second-direction features in a particular cell may be located on a common layer of the sample 108 (e.g., a current layer or a previous layer). In this configuration, the first-direction features and the second-direction features may form 2D features. As another example, the first-direction features and the second-direction features in a particular cell may be located on different layers of the sample 108.

FIG. 2A depicts top views of one non-limiting design of an overlay target formed as a cross-hatched target, in accordance with one or more embodiments of the present disclosure. In particular, FIG. 2A depicts a current layer 200 in a first panel, a previous layer 208 in a second panel, and the complete overlay target 106 in a third panel.

In FIG. 2A, the overlay target 106 includes four cells (cell 202a, cell 202b, cell 202c, and cell 202d) arranged as quadrants in a square configuration. Cells 202a and 202b form one pair of opposing quadrants (e.g., first cells) and each include y-periodic features 206 in a current layer 200 and x-periodic features 204 in a previous layer 208. Cells 202c and 202d form another pair of opposing quadrants (e.g., second cells) and each include x-periodic features 204 in the current layer 200 and y-periodic features 206 in a previous layer 208. Further, the first cells and the second cells may be designed to have a common center of symmetry such that measured differences between centers of symmetry of the first cells and the second cells may be attributed to overlay error. It is to be understood that although FIG. 2A depicts the x-periodic features 204 and y-periodic features 206 in a single previous layer 208, this is not a requirement. In some embodiments, the x-periodic features 204 and the y-periodic features 206 are located in another layer.

In this configuration, the complete overlay target 106 may be characterized as a having cross-hatched target design. This cross-hatched design allows for compact overlay measurements in both x and y directions by incorporating both x-periodic features 204 and y-periodic features 206 within each cell of the overlay target 106.

FIG. 2B illustrates a schematic view of another non-limiting design of an overlay target 106 including 2D features 210 each cell, in accordance with one or more embodiments of the present disclosure. This is another non-limiting example of the overlay target 106 and may be referred to as a variant of an advanced imaging metrology in-die (AlMid) target. In FIG. 2B, each cell includes x-periodic features 204 and y-periodic features 206 on a common layer of the sample 108, which are together referred to as 2D features 210. For example, cells 202a and 202b (e.g., first cells) include 2D features 210 on a current layer 200, while cells 202c and 202d (e.g., second cells) include 2D features 210 on a previous layer 208. Further, the 2D features 210 may have any size or shape and may exhibit periodicity in multiple directions. For example, FIG. 2B depicts 2D features 210 in the current layer 200 as box features and 2D features 210 in the previous layer 208 as rectangular features, but this is merely an illustration. Further, the first cells and the second cells may be designed to have a common center of symmetry such that measured differences between centers of symmetry of the first cells and the second cells may be attributed to overlay error.

FIG. 2C illustrates another non-limiting example of an overlay target 106 including both 2D features 210 and cross-hatched features, in accordance with one or more embodiments of the present disclosure. In this configuration, cells 202a and 202b (e.g., first cells) may include 2D features 210 in a current layer 200 in a manner similar to FIG. 2B. Cells 202c and 202d (e.g., second cells) may include cross-hatched features similar to FIG. 2A. For example, cells 202c and 202d may include x-periodic features 204 and y-periodic features 206 in different layers of the sample 108. Further, the first cells and the second cells may be designed to have a common center of symmetry such that measured differences between centers of symmetry of the first cells and the second cells may be attributed to overlay error.

The 2D mixed target design facilitates compact overlay measurements in both directions by combining elements of the cross-hatched and AlMid designs. The 2D features 210 in cells 202a and 202b allow for simultaneous x and y measurements in the current layer 200, while the cross-hatched features in cells 202c and 202d enable overlay measurements between different layers.

Referring now generally to FIGS. 2A-2C, it is contemplated herein that FIGS. 2A-2C and the associated descriptions are provided solely for illustrative purposes and should not be interpreted as limiting the scope of the present disclosure. For example, FIGS. 2A-2C all depict configurations with a first group of two cells associated with a current layer 200 and a second group of cells associated with a previous layer 208. However, an overlay target 106 may include any number of cells in any arrangement.

Further, as described previously herein, properties of the overlay target 106 may be co-selected via a metrology recipe with properties of the overlay metrology system 100 to provide that the diffracted light 112 includes selected diffraction orders from each illumination dipole 104. For example, the pitches of the first-direction features (e.g., x-periodic features 204) and the second-direction features (e.g., y-periodic features 206) may be selected in accordance with the metrology recipe based on known properties of a first illumination dipole 104 and a second illumination dipole 104 to provide that only x-periodic features 204 are resolved in a first image (e.g., an x-direction image) and that only y-periodic features 206 are resolved in a second image (e.g., a y-direction image).

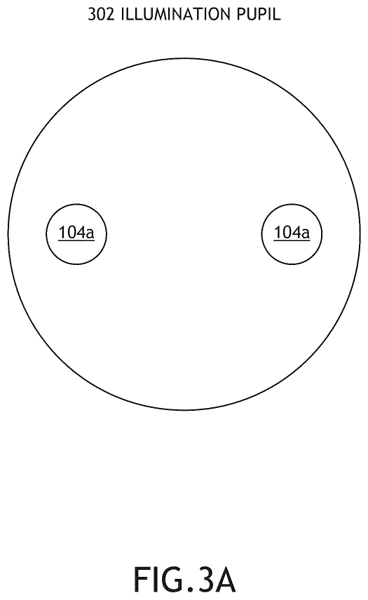

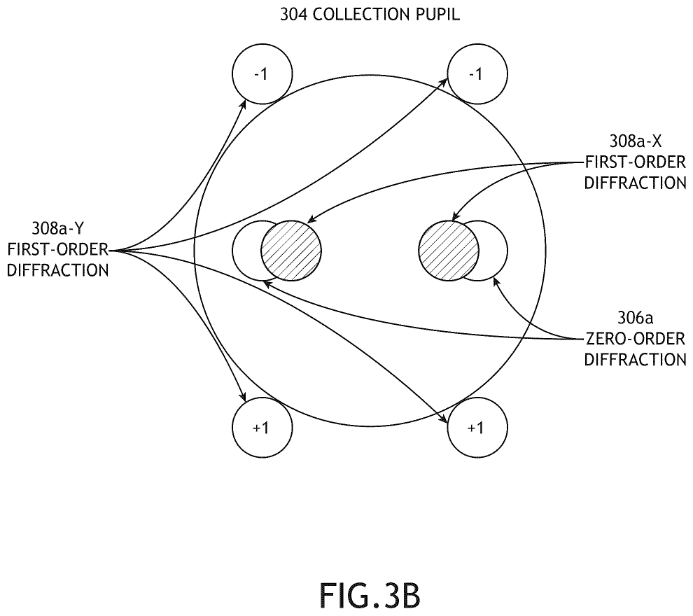

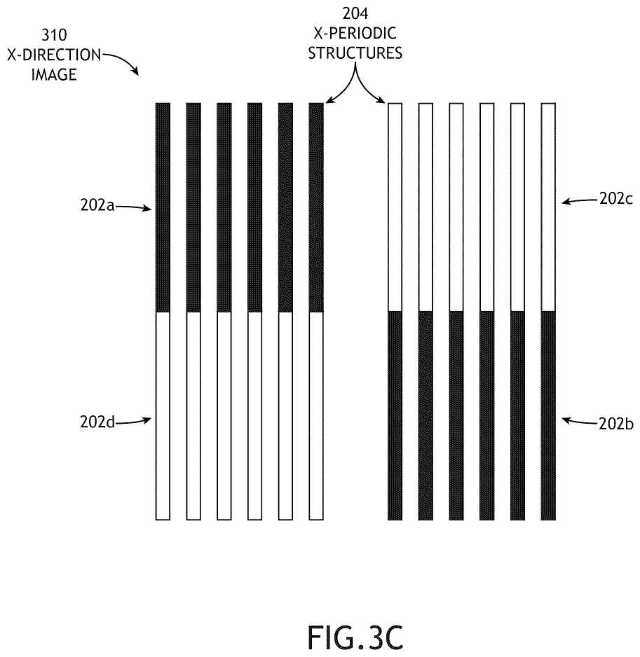

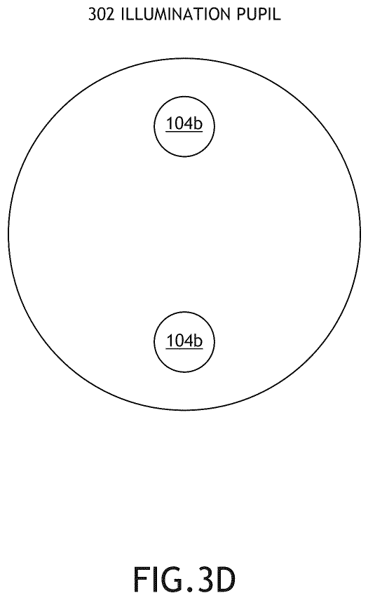

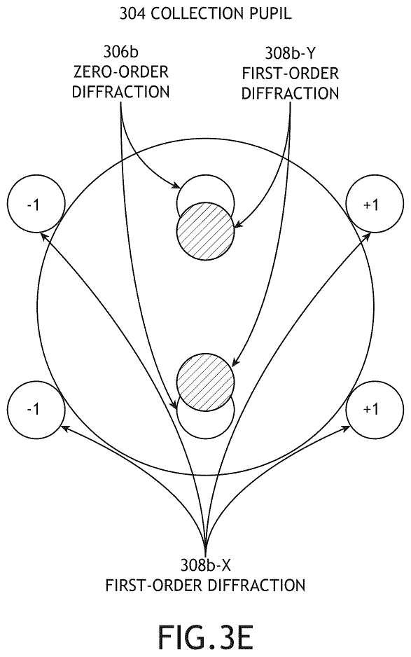

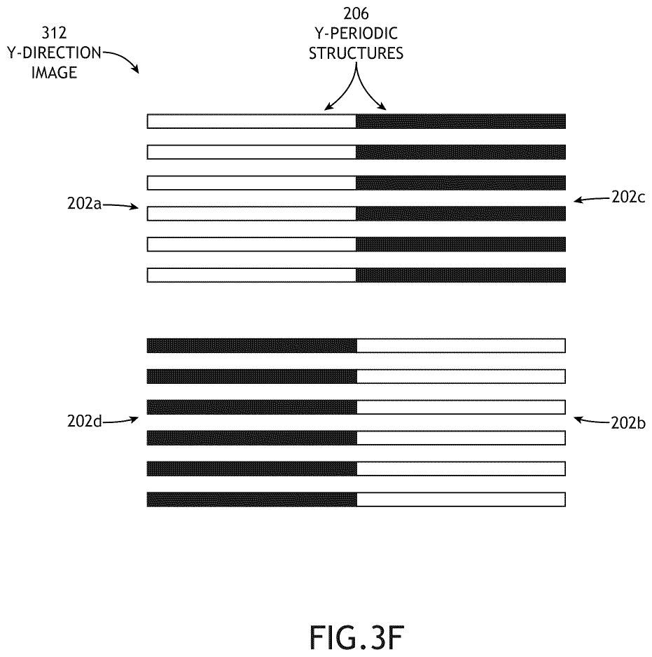

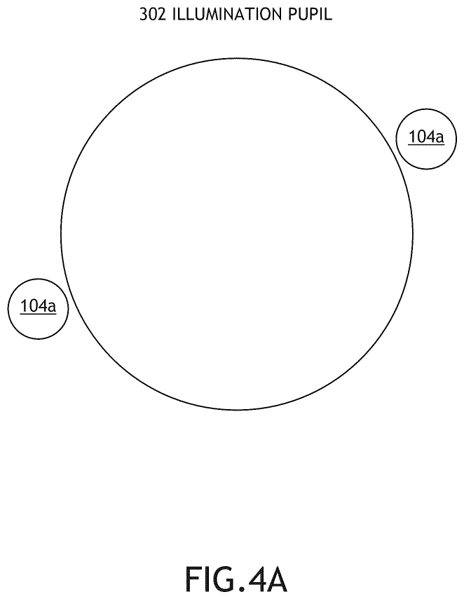

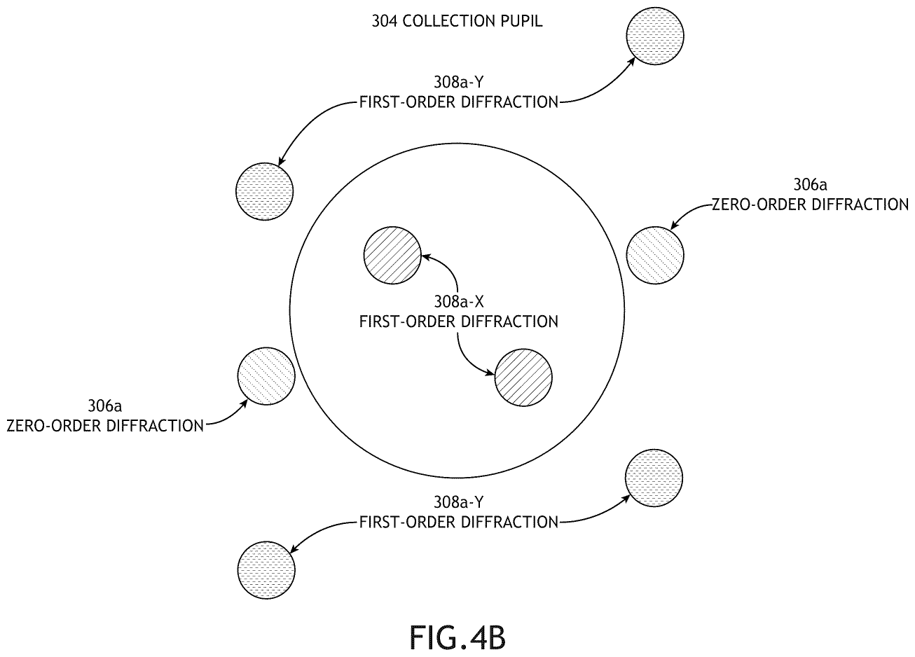

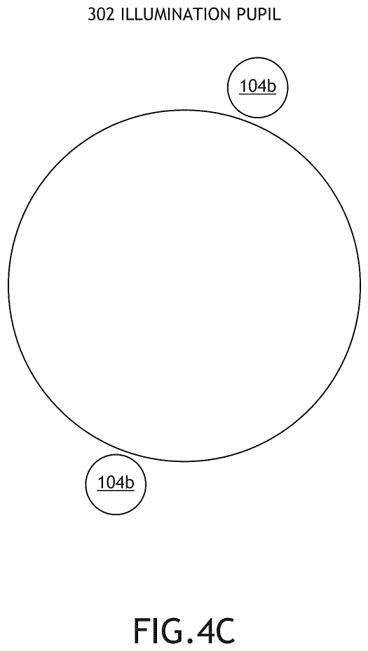

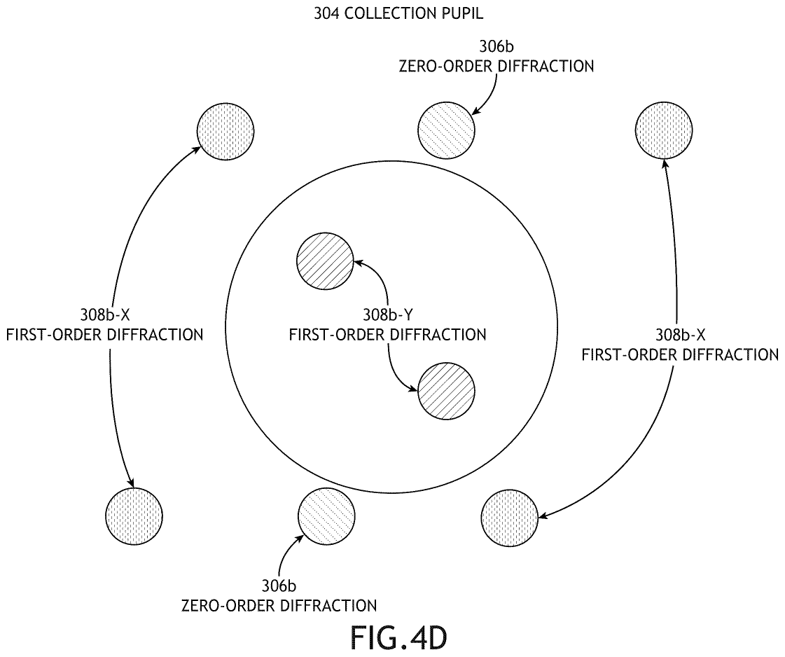

Referring now to FIGS. 3A-4D, generating direction-isolated images of an overlay target 106 with two illumination dipoles 104 (labeled as a first illumination dipole 104a and a second illumination dipole 104b) is described in greater detail, in accordance with one or more embodiments of the present disclosure.

FIGS. 3A-3F illustrate a through-the-lens illumination and collection configuration for both X-direction and Y-direction measurements, in accordance with one or more embodiments of the present disclosure. The illumination dipoles 104 and collection pupils are configured to resolve X-direction features (FIGS. 3A, 3B, 3C) and Y-direction features (FIGS. 3D, 3E, 3F) while suppressing features in the orthogonal direction. This configuration may be suitable for, but not limited to, incoherent imaging with incoherent illumination dipoles 104.

FIGS. 3A and 3B illustrate schematic views of illumination and collection pupils for the overlay metrology system 100, where the illumination includes an illumination dipole 104a oriented along the X direction, in accordance with one or more embodiments of the present disclosure.

FIG. 3A illustrates an illumination pupil 302 with an illumination dipole 104a oriented along the X direction, in accordance with one or more embodiments of the present disclosure. In particular, the illumination dipole 104a is shown as two illumination lobes oriented symmetrically along the X direction and within a boundary associated with the numerical aperture of the objective lens 128. In this way, FIG. 3A corresponds to a through-the-lens (TTL) illumination configuration.

FIG. 3B illustrates a circular collection pupil 304 associated with the illumination distribution of FIG. 3A, in accordance with one or more embodiments of the present disclosure. In FIG. 3B, zero-order diffraction 306a associated with zero-order diffraction of the first illumination dipole 104a lies within the collection pupil 304 based on the TTL configuration of FIG. 3A. Additionally, x-direction first-order diffraction 308a-X of the first illumination dipole 104a falls inside the collection pupil 304 and may thus contribute to imaging. However, y-direction first-order diffraction 308a-Y of the first illumination dipole 104a falls outside the collection pupil 304 and does not contribute to imaging. This configuration enables selective imaging of features along the X direction, where the x-periodic features 204 are resolved and y-periodic features 206 are unresolved.

FIG. 3C illustrates an x-direction image 310 of the overlay target 106 generated based on the illumination pupil 302 and the collection pupil 304 in FIGS. 3A and 3B, in accordance with one or more embodiments of the present disclosure. Further, the image in FIG. 3C may illustrate isolated imaging of x-periodic features 204 in a cross-hatched overlay target 106 as shown in FIG. 2A. As shown in FIG. 3C, the x-periodic features 204 are resolved, while the y-periodic features 206 are unresolved.

FIGS. 3D and 3E illustrate schematic views of illumination and collection pupils for the overlay metrology system 100, where the illumination includes an illumination dipole 104 (e.g., a second illumination dipole 104b) oriented along the Y direction, in accordance with one or more embodiments of the present disclosure.

FIG. 3D illustrates an illumination pupil 302 with an illumination dipole 104 oriented along the Y direction, in accordance with one or more embodiments of the present disclosure. In particular, the illumination dipole 104b is shown as two illumination lobes oriented symmetrically along the Y direction and also within the numerical aperture of the objective lens 128. In this way, FIG. 3D also corresponds to a through-the-lens (TTL) illumination configuration.

FIG. 3E illustrates a circular collection pupil 304 associated with the illumination distribution of FIG. 3D, in accordance with one or more embodiments of the present disclosure. In FIG. 3E, zero-order diffraction 306b of the second illumination dipole 104b lies within the collection pupil 304 based on the TTL configuration of FIG. 3D. Additionally, y-direction first-order diffraction 308b-Y of the second illumination dipole 104 falls inside the collection pupil 304 and may thus contribute to imaging. However, x-direction first-order diffraction 308b-X of the second illumination dipole 104b falls outside the collection pupil 304 and does not contribute to imaging. This configuration enables selective imaging of features along the Y direction, where y-periodic features 206 are resolved and x-periodic features 204 are unresolved.

FIG. 3F illustrates a y-direction image 312 of the overlay target 106 generated based on the illumination pupil 302 and the collection pupil 304 in FIGS. 3D and 3E, in accordance with one or more embodiments of the present disclosure. As with FIG. 3C, the y-direction image 312 may be generated based on the illumination and collection pupils in FIGS. 3D and 3E. This image may illustrate isolated imaging of y-periodic features 206 in a cross-hatched overlay target 106 as shown in FIG. 2A.

It is contemplated herein that the distributions of diffraction lobes in FIG. 3B and FIG. 3E that provide direction-isolated imaging (e.g., as shown in FIG. 3C and FIG. 3F) may be enabled through the co-selection of parameters of the first and second illumination dipoles 104 (e.g., wavelength, incidence angle (e.g., location in the illumination pupil 302), or the like) as well as the properties of the x-periodic features 204 and y-periodic features 206 in the various cells (e.g., the pitch, number of features per cell, or the like) through a metrology recipe.

Further, the x-direction image 310 of FIG. 3C and the y-direction image 312 of FIG. 3E may be generated either sequentially or simultaneously.

For example, sequential imaging may be provided by first illuminating the overlay target 106 with the first illumination dipole 104a in FIG. 3A and generating a first image based on the collection pupil 304 of FIG. 3B on a detector 132 and then illuminating the overlay target 106 with the second illumination dipole 104b in FIG. 3D and generating a second image based on the collection pupil 304 of FIG. 3E on the detector 132 detector.

As another example, simultaneous imaging may be provided by simultaneously illuminating the overlay target 106 with both the first illumination dipole 104 (e.g., as shown in FIG. 3A) and the second illumination dipole 104 (e.g., as shown in FIG. 3D). In this configuration, the objective lens 128 may simultaneously collect diffracted light 112 corresponding to both the collection pupil 304 distributions in FIG. 3B and FIG. 3E, where channel-splitting optics 142 may direct diffraction lobes associated with the different illumination dipoles 104a-b to different detectors 132 based on characteristics such as, but not limited to, wavelength, polarization, or location in the collection pupil 304.

Further, the TTL configurations depicted in FIGS. 3A-3F may utilized using illumination dipoles 104 with any degree of spatial or temporal coherence.

Referring now to FIGS. 4A-4D, OTL illumination and collection for both X-direction and Y-direction measurements are described, in accordance with one or more embodiments of the present disclosure. The illumination dipoles 104 and collection pupils are configured to resolve X-direction features (FIGS. 4A-4B) and Y-direction features (FIGS. 4C-4D) while suppressing features in the orthogonal direction. This configuration may be suitable for, but not limited to, coherent imaging with illumination dipoles 104 having mutually-coherent diffraction lobes.

FIGS. 4A and 4B illustrate schematic diagrams of illumination and collection pupils for direction-isolated imaging along the X direction, in accordance with one or more embodiments of the present disclosure.

FIG. 4A illustrates an illumination pupil 302 with a first illumination dipole 104a, in accordance with one of the more embodiments of the present disclosure. In FIG. 4A, the first illumination dipole 104a includes illumination lobes located outside a boundary indicative of the numerical aperture of the objective lens 128 to provide OTL illumination. Further, the first illumination dipole 104a is rotated with respect to the X direction and may thus be characterized as a rotated dipole. This configuration may enable greater control and separation of diffraction lobes in the collection pupil 304.

FIG. 4B illustrates a circular collection pupil 304 associated with the illumination distribution in FIG. 4A. In FIG. 4B, x-direction first-order diffraction 308a-X of the first illumination dipole 104a falls inside the collection pupil 304 and may thus contribute to imaging. However, zero-order diffraction 306a associated with zero-order diffraction of the first illumination dipole 104 lies outside the collection pupil 304 based on the OTL configuration of FIG. 4A. Further, y-direction first-order diffraction 308a-Y of the first illumination dipole 104a also falls outside the collection pupil 304. This configuration enables selective imaging of features along the X direction, where the x-periodic features 204 are resolved and y-periodic features 206 are unresolved.

FIGS. 4C and 4D illustrate schematic diagrams of illumination and collection pupils for direction-isolated imaging along the Y direction, in accordance with one or more embodiments of the present disclosure.

FIG. 4C illustrates an illumination pupil 302 with a second illumination dipole 104b, in accordance with one of the more embodiments of the present disclosure. In FIG. 4C, the second illumination dipole 104b includes illumination lobes located outside a boundary indicative of the numerical aperture of the objective lens 128 and rotated with respect to the Y direction (e.g., as another rotated dipole).

FIG. 4D illustrates a circular collection pupil 304 associated with the illumination distribution in FIG. 4C. In FIG. 4D, y-direction first-order diffraction 308b-Y of the second illumination dipole 104 falls inside the collection pupil 304 and may thus contribute to imaging. However, zero-order diffraction 306b associated with zero-order diffraction of the second illumination dipole 104b lies outside the collection pupil 304 based on the OTL configuration of FIG. 4A. Further, x-direction first-order diffraction 308b-X of the second illumination dipole 104b also falls outside the collection pupil 304. This configuration enables selective imaging of features along the Y direction, where the y-periodic features 206 are resolved and x-periodic features 204 are unresolved.

It is contemplated herein that the OTL techniques in which associated direction-isolated images are generated only with first-order diffraction lobes (e.g., as shown in FIG. 4B and FIG. 4D) may correspond to a dark-field imaging technique. Further, in the case of mutually-coherent illumination dipoles 104, an imaged cell may be represented by an interference pattern (e.g., interference fringes) associated with interference of the mutually-coherent illumination lobes. The orientation of these interference fringes as well as the imaged pitch may differ from the printed features and may rather be based on the orientation and position of the illumination dipole 104. For example, an image of x-periodic features 204 generated based on the distribution in FIG. 4B may include interference fringes oriented with a direction of periodicity corresponding to a direction of separation of the x-direction first-order diffraction 308a-X. Similarly, an image of y-periodic features 206 generated based on the distribution in FIG. 4D may include interference fringes oriented with a direction of periodicity corresponding to a direction of separation of the y-direction first-order diffraction 308b-Y.

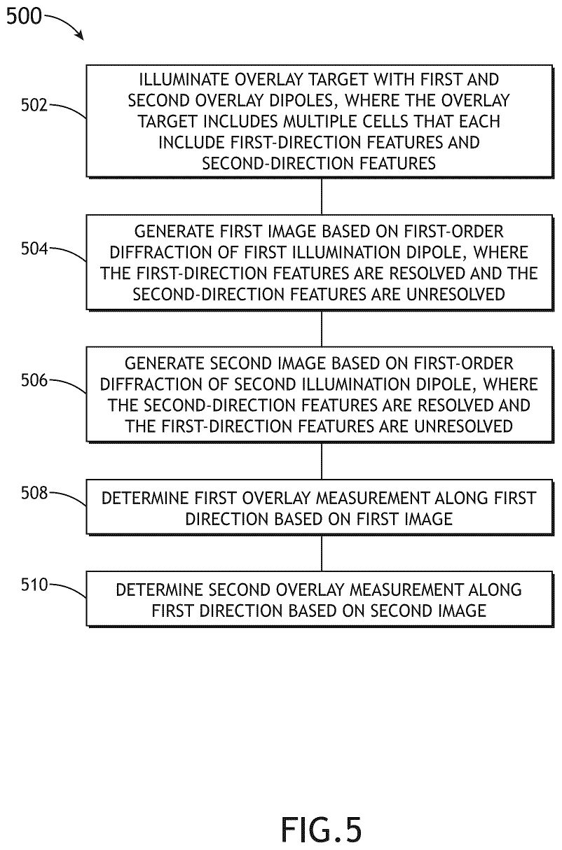

FIG. 5 illustrates a flowchart of a method 500 for performing overlay measurements, in accordance with one or more embodiments of the present disclosure. The embodiments and enabling technologies described in the context of the overlay metrology system 100 may be interpreted to extend to the method 500. For example, the method 500 may be implemented using the overlay metrology system 100 described herein. However, the method 500 may not be limited to the specific architecture of the overlay metrology system 100.

In some embodiments, the method 500 includes a step 502 of illuminating an overlay target with first and second illumination dipoles. For example, the illumination subsystem 102 of the overlay metrology system 100 may direct a first illumination dipole 104 and a second illumination dipole 104 to the overlay target 106 positioned on the sample 108. The overlay target 106 may include two or more cells, where each cell comprises first-direction features having periodicity along a first direction and second-direction features having periodicity along a second direction. In some cases, the first direction may be an x-direction and the second direction may be a y-direction, where the x-direction and y-direction are orthogonal to each other.

In some embodiments, the method 500 includes a step 504 of generating a first image based on first-order diffraction of the first illumination dipole. For instance, the imaging subsystem 110 of the overlay metrology system 100 may collect diffracted light 112 from the overlay target 106 and form the first image on a detector 132. In this first image, the first-direction features may be resolved while the second-direction features may be unresolved. For example, if the first direction is the x-direction, the x-periodic features 204 may be resolved in the first image while the y-periodic features 206 may be unresolved (e.g., due to first-order diffraction and higher-order diffraction along the Y direction falling outside the collection numerical aperture of the objective lens 128).

In some embodiments, the method 500 includes a step 506 of generating a second image based on first-order diffraction of the second illumination dipole. Similar to the generation of the first image, the imaging subsystem 110 may collect diffracted light 112 from the overlay target 106 and form the second image on a detector 132. In this second image, the second-direction features may be resolved while the first-direction features may be unresolved. For example, if the second direction is the y-direction, the y-periodic features 206 may be resolved in the second image while the x-periodic features 204 may be unresolved (e.g., due to first-order diffraction and higher-order diffraction along the X direction falling outside the collection numerical aperture of the objective lens 128).

In some cases, the first image and the second image may be generated simultaneously using separate detectors 132. For example, the imaging subsystem 110 may include channel-splitting optics 142 to direct the diffracted light 112 associated with the first illumination dipole 104 to a first detector 132 and the diffracted light 112 associated with the second illumination dipole 104 to a second detector 132.

In some embodiments, the method 500 may include separating the diffracted light 112 associated with different illumination dipoles 104 using channel-splitting optics 142. For example, the channel-splitting optics 142 may include various components such as wavelength-selective filters, polarization-selective elements, or prisms positioned in the collection pupil 304 to separate the diffracted light 112 based on wavelength, polarization, or spatial distribution, respectively.

In some embodiments, the method 500 may include sequential imaging of the overlay target 106. For example, the first image may be generated based on illumination with the first illumination dipole 104 and collection of diffracted light 112 by the detector 132, followed by generation of the second image based on illumination with the second illumination dipole 104 and collection of diffracted light 112 by the same detector 132. This sequential approach may allow for the use of a single detector 132 to capture both the first image and the second image in succession.

In some embodiments, the method 500 includes a step 508 of determining a first overlay measurement along the first direction based on the first image. For example, the controller 114 of the overlay metrology system 100 may analyze the first image to determine the overlay measurement along the x-direction.

In some embodiments, the method 500 includes a step 510 of determining a second overlay measurement along the second direction based on the second image. For instance, the controller 114 may analyze the second image to determine the overlay measurement along the y-direction.

The steps 508 and 510 may include determination of an overlay measurement using any technique known in the art including, but not limited to, determining an overlay measurement based on differences of centers of symmetry of features on different layers of the sample 108.

For simultaneous measurements where both first-direction and second-direction features are captured in a single image, the controller 114 may implement a combined modeling approach. This may involve first separating the contributions from each direction through filtering in the frequency domain, followed by independent modeling of each component. The accuracy of such modeling approaches depends on the angular separation between the first-direction and second-direction features, with larger angular separations generally allowing for more accurate decomposition and modeling.

For example, when the imaged fringes associated with the first-direction features and second-direction features are orthogonal to each other, simple projection-based separation of signals may be sufficient. In such cases, the controller 114 may implement a 2D model fitting approach to accurately extract overlay information from the complex image patterns. For example, the controller 114 may fit a model of the form:

$${\sum }_{i} ( {a}_{i} sin ( \frac{2 π i}{{P}_{x}} x ) + {b}_{i} cos ( \frac{2 π i}{{P}_{x}} x ) ) {\sum }_{j} ( {c}_{j} sin ( \frac{2 π j}{{P}_{y}} y ) + {d}_{j} cos ( \frac{2 π j}{{P}_{y}} y ) )$$

where Pₓ and P_{y} are the visual pitches of the x and y fringes in the image, respectively, which may differ from the actual pitches of the features of the overlay target 106. The coefficients aᵢ, bᵢ, cⱼ, and dⱼ are determined through a fitting process to match the observed image intensity patterns. A variation of such an approach may be used when the imaged fringes associated with the first-direction features and second-direction features are not orthogonal to each other, but are sufficiently far from parallel that the contributions associated with the different illumination dipoles 104 may be distinguished by the model.

In some embodiments, the method 500 may include a step of providing correctables to one or more process tools based on the overlay measurements. The correctables may be used to adjust process parameters in subsequent manufacturing steps, potentially improving overall process control and yield. In a feedback configuration, the overlay measurements from a completed wafer or lot may be used to adjust process parameters for future wafers or lots, helping to compensate for systematic errors or drifts in the manufacturing process. Alternatively, in a feed-forward configuration, the overlay measurements from initial layers of a wafer may be used to adjust process parameters for subsequent layers on the same wafer, potentially allowing for real-time corrections to be applied during the manufacturing process. The controller 114 may generate these correctables based on the overlay measurements and communicate them to relevant process tools such as lithography systems, etching tools, or deposition equipment. In some cases, the correctables may be applied using a combination of feedback and feed-forward techniques to optimize process control across multiple time scales and manufacturing steps.

The herein described subject matter sometimes illustrates different components contained within, or connected with, other components. It is to be understood that such depicted architectures are merely exemplary, and that in fact many other architectures can be implemented which achieve the same functionality. In a conceptual sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “connected” or “coupled” to each other to achieve the desired functionality, and any two components capable of being so associated can also be viewed as being “couplable” to each other to achieve the desired functionality. Specific examples of couplable include but are not limited to physically interactable and/or physically interacting components and/or wirelessly interactable and/or wirelessly interacting components and/or logically interactable and/or logically interacting components.

It is believed that the present disclosure and many of its attendant advantages will be understood by the foregoing description, and it will be apparent that various changes may be made in the form, construction, and arrangement of the components without departing from the disclosed subject matter or without sacrificing all of its material advantages. The form described is merely explanatory, and it is the intention of the following claims to encompass and include such changes. Furthermore, it is to be understood that the invention is defined by the appended claims.

What is claimed:

1. An overlay metrology system comprising:
an illumination sub-system including one or more lenses configured to direct illumination to an overlay target on a sample when implementing a metrology recipe, wherein the illumination comprises a first illumination dipole and a second illumination dipole, wherein the overlay target in accordance with the metrology recipe includes two or more cells, wherein each cell of the two or more cells comprises first-direction features having periodicity along a first direction and second-direction features having periodicity along a second direction;
an imaging sub-system including an objective lens configured to collect diffraction orders of the illumination generated by the overlay target and further including one or more detectors, wherein the illumination sub-system and the imaging sub-system are configured in accordance with the metrology recipe to:
generate a first image of the overlay target based on first-order diffraction of the first illumination dipole by the first-direction features, wherein the first-direction features are resolved and the second-direction features are unresolved on the first image; and
generate a second image of the overlay target based on first-order diffraction of the second illumination dipole by the second-direction features, wherein the second-direction features are resolved and the first-direction features are unresolved in the second image; and
a controller including one or more processors configured to execute program instructions causing the one or more processors to generate a first overlay measurement along the first direction based on the first image and generate a second overlay measurement along the second direction based on the second image.

2. The overlay metrology system of claim 1, wherein the illumination sub-system and the imaging sub-system are configured in accordance with the metrology recipe to provide that first-order diffraction from the second-direction features is outside a collection numerical aperture of the objective lens when generating the first image and further provide that first-order diffraction from the first-direction features is outside the collection numerical aperture of the objective lens when generating the second image.

3. The overlay metrology system of claim 1, wherein the illumination sub-system and the imaging sub-system are configured in accordance with the metrology recipe to provide that first-order diffraction from the second-direction features is blocked when generating the first image and further provide that first-order diffraction from the first-direction features is blocked when generating the second image.

4. The overlay metrology system of claim 1, wherein the one or more detectors comprise:
a first detector configured to generate the first image; and
a second detector configured to generate the second image simultaneously with the first image.

5. The overlay metrology system of claim 4, wherein the first illumination dipole and the second illumination dipole have different wavelengths, wherein the imaging sub-system further includes one or more wavelength-selective optics to direct the first-order diffraction of the first illumination dipole by the first-direction features to the first detector and direct the first-order diffraction of the second illumination dipole by the second-direction features to the second detector.

6. The overlay metrology system of claim 4, wherein the first illumination dipole and the second illumination dipole have orthogonal polarizations, wherein the imaging sub-system further includes one or more polarization-selective optics to direct the first-order diffraction of the first illumination dipole by the first-direction features to the first detector and direct the first-order diffraction of the second illumination dipole by the second-direction features to the second detector.

7. The overlay metrology system of claim 4, wherein the imaging sub-system further includes one or more prisms in a collection pupil to direct the first-order diffraction of the first illumination dipole by the first-direction features to the first detector and direct the first-order diffraction of the second illumination dipole by the second-direction features to the second detector.

8. The overlay metrology system of claim 1, wherein the first illumination dipole includes a first pair of mutually-coherent beams, wherein the second illumination dipole includes a second pair of mutually-coherent beams.

9. The overlay metrology system of claim 8, wherein the first pair of mutually-coherent beams and the second pair of mutually-coherent beams are incoherent with respect to each other.

10. The overlay metrology system of claim 8, wherein the illumination sub-system directs the first pair of mutually-coherent beams and the second pair of mutually-coherent beams to the overlay target at incidence angles outside a collection numerical aperture of the objective lens.

11. The overlay metrology system of claim 1, wherein the illumination is at least one of spatially or temporally incoherent.

12. The overlay metrology system of claim 11, wherein the illumination sub-system directs the first illumination dipole and the second illumination dipole to the overlay target through the objective lens.

13. The overlay metrology system of claim 1, wherein the two or more cells of the overlay target include:
one or more first cells, wherein the first-direction features and the second-direction features in the one or more first cells are located in a first layer of the sample; and
one or more second cells, wherein the first-direction features in the one or more second cells are located in a second layer of the sample, wherein the second-direction features in the one or more second cells are located in a third layer of the sample.

14. The overlay metrology system of claim 13, wherein the one or more first cells and the one or more second cells have a common center of symmetry by design.

15. The overlay metrology system of claim 1, wherein the two or more cells of the overlay target include:
one or more first cells, wherein the first-direction features and the second-direction features in the one or more first cells are located in a first layer of the sample; and
one or more second cells, wherein the first-direction features and the second-direction features in the one or more second cells are located in a second layer of the sample.

16. The overlay metrology system of claim 15, wherein the one or more first cells and the one or more second cells have a common center of symmetry by design.

17. The overlay metrology system of claim 1, wherein the two or more cells of the overlay target include:
one or more first cells, wherein the first-direction features in the one or more first cells are located in a first layer of the sample, wherein the second-direction features in the one or more first cells are located in a second layer of the sample; and
one or more second cells, wherein the first-direction features in the one or more second cells are located in the first layer of the sample.

18. The overlay metrology system of claim 17, wherein the second-direction features in the one or more first cells are located in the second layer of the sample.

19. The overlay metrology system of claim 17, wherein the second-direction features in the one or more first cells are located in a third layer of the sample.

20. The overlay metrology system of claim 17, wherein the one or more first cells and the one or more second cells have a common center of symmetry by design.

21. An overlay metrology method comprising:
illuminating an overlay target on a sample with illumination comprising a first illumination dipole and a second illumination dipole, wherein the overlay target includes two or more cells, wherein each cell of the two or more cells comprises first-direction features having periodicity along a first direction and second-direction features having periodicity along a second direction;
generating first image on a first detector based on first-order diffraction of the first illumination dipole by the first-direction features, wherein the first-direction features are resolved and the second-direction features are unresolved in the first image;
generating a second image of the overlay target based on first-order diffraction of the second illumination dipole by the second-direction features, wherein the second-direction features are resolved and the first-direction features are unresolved in the second image; and
determining a first overlay measurement along the first direction based on the first image and generate a second overlay measurement along the second direction based on the second image.

22. An overlay metrology target comprising:
two or more cells on a sample, wherein each cell of the two or more cells comprises first-direction features having periodicity along a first direction and second-direction features having periodicity along a second direction, wherein the two or more cells comprise:
one or more first cells, wherein the first-direction features and the second-direction features in the one or more first cells are located in a first layer of the sample; and
one or more second cells, wherein the first-direction features in the one or more second cells are located in a second layer of the sample, wherein the second-direction features in the one or more second cells are located in a third layer of the sample.

23. The overlay metrology target of claim 22, wherein the one or more first cells and the one or more second cells have a common center of symmetry by design.

24. The overlay metrology target of claim 22, wherein pitches of the first-direction features and the second-direction features are selected in accordance with a metrology recipe based on known properties of a first illumination dipole and a second illumination dipole of an overlay metrology system configured to generate overlay measurements of the overlay metrology target, wherein the metrology recipe provides that first-order diffraction from the second-direction features is outside a collection numerical aperture of an objective lens of the overlay metrology system and further provides that first-order diffraction from the first-direction features is outside the collection numerical aperture of the objective lens.
